(19) United States
(12) Patent Application Publication
(10) Pub. No.: US 2025/0176366 A1
(43) Pub. Date: May 29, 2025

(54) DISPLAY PANEL, AND METHOD FOR MANUFACTURING DISPLAY PANEL

(71) Applicant: Visionox Technology Inc., Jiangsu (CN)

(72) Inventors: Chao Chi PENG, Jiangsu (CN); Yahong LIU, Jiangsu (CN)

(73) Assignee: Visionox Technology Inc., Jiangsu (CN)

(21) Appl. No.: 18/940,005

(22) Filed: Nov. 7, 2024

(30) Foreign Application Priority Data
Nov. 29, 2023 (CN) 202311615990.5

(51) Int. Cl. H10K 59/122; H10K 59/12; H10K 59/80

(52) U.S. Cl. CPC H10K 59/122; H10K 59/1201; H10K 59/873

(57) ABSTRACT

A display panel, and a method for manufacturing a display panel. The display panel includes a base plate, an isolation structure, a light-emitting functional layer, an encapsulation protection layer, and an optical functional portion. The isolation structure is arranged at one side of the base plate and encircles a plurality of isolation openings. The light-emitting functional layer is arranged at one side of the base plate and includes a light-emitting structure. The encapsulation protection layer is arranged at a side of the light-emitting functional layer away from the base plate and partially embedded in the isolation opening. The optical functional portion is arranged in the encapsulation protection layer, and an orthographic projection of the optical functional portion on the base plate overlaps an orthographic projection of at least one of the isolation structure or the light-emitting structure on the base plate.

### CROSS REFERENCE TO RELATED APPLICATION

The present application claims priority to Chinese Patent Application No. 202311615990.5 filed on Nov. 29, 2023, which is incorporated herein by reference in its entirety.

### TECHNICAL FIELD

The present application relates to the field of display technology, and particularly to a display panel, and a method for manufacturing a display panel.

### BACKGROUND

Planar display panels such as Organic Light Emitting Diode (OLED) display panels and display panels using Light Emitting Diode (LED) devices, etc., are widely used in cell phones, TVs, personal digital assistants, digital cameras, notebook computers, desktop computers and other consumer electronic products due to their high image quality, power saving, thin body and wide range of applications, and have become the mainstream of the display apparatus.

### SUMMARY

Embodiments of the present application provide a display panel, a display apparatus, and a method for manufacturing a display panel, which can improve the display effect.

In a first aspect, some embodiments of the present application provide a display panel. The display panel includes a base plate, an isolation structure, a light-emitting functional layer, an encapsulation protection layer, and an optical functional portion. The isolation structure is arranged at one side of the base plate and encircles a plurality of isolation openings. The light-emitting functional layer is arranged at one side of the base plate and includes a light-emitting structure arranged corresponding to the isolation opening.

The encapsulation protection layer is arranged at a side of the light-emitting functional layer away from the base plate, The encapsulation protection layer comprises a first encapsulation layer, the first encapsulation layer comprises a plurality of first encapsulation portions respectively arranged in the plurality of isolation openings.

The optical functional portion comprises a plurality of second adjustment portions, the second adjustment portions located at a side of the first encapsulation portion away from the base plate, and the second adjustment portion at least partially embedded in the isolation opening, the second adjustment portion comprises a color filter.

In some embodiments, the first adjustment portion comprises a black matrix.

In some embodiments, an orthographic projection of the first adjustment portion on the base plate covers the orthographic projection of the second isolation portion on the base plate.

In a second aspect, some embodiments of the present application provide a display panel. The display panel includes a base plate, an isolation structure, a light-emitting functional layer, an encapsulation protection layer, and an optical functional portion. The isolation structure is arranged at one side of the base plate and encircles a plurality of isolation openings. The light-emitting functional layer is arranged at one side of the base plate and includes a light-emitting structure arranged corresponding to the isolation opening.

The encapsulation protection layer is arranged at a side of the light-emitting functional layer away from the base plate and partially embedded in the isolation opening. The optical functional portion is arranged in the encapsulation protection layer, and an orthographic projection of the optical functional portion on the base plate overlaps an orthographic projection of at least one of the isolation structure or the light-emitting structure on the base plate.

In some embodiments, the isolation structure further comprises a third isolation portion arranged at a side of the first isolation portion facing the base plate, and the third isolation portion comprises an electrically conductive material and is electrically connected with the first isolation portion; and the orthographic projection of the first isolation portion on the base plate is located within an orthographic projection of the third isolation portion on the base plate, and the first electrode contacts the third isolation portion.

In some embodiments, the orthographic projection of the first adjustment portion on the base plate covers the orthographic projection of the second isolation portion on the base plate and at least a portion of the light-emitting structure.

In some embodiments, the second adjustment portion comprises a first surface at a side away from the base plate, the first surface is parallel to a plane in which the base plate is located.

In some embodiments, the isolation structure comprises a first isolation portion and a second isolation portion that are stacked in sequence along a direction away from the base plate, and an orthographic projection of the first isolation portion on the base plate is located within an orthographic projection of the second isolation portion on the base plate.

In some embodiments, the first encapsulation portion comprises a second portion arranged in contact with the first isolation portion, a third portion arranged in contact with the second isolation portion, and a fourth portion connected with the second portion and covering the light-emitting structure; the third portion and the fourth portion are spaced apart in a thickness direction of the base plate to form a gap space, and the second adjustment portion is at least partially located at a side of the gap space away from the base plate; and the second adjustment portion is partially located within the gap space.

In some embodiments, the encapsulation protection layer further comprises the second encapsulation layer and a third encapsulation layer that are stacked in sequence at the side of the first encapsulation layer away from the base plate, the second adjustment portion is located between the first encapsulation layer and the second encapsulation layer, and the first adjustment portion is located between the second encapsulation layer and the third encapsulation layer.

In a third aspect, some embodiments of the present application provide a display apparatus, including the display panel according to any of the above implementations.

In a fourth aspect, some embodiments of the present application provide a method for manufacturing a display panel, including: forming an isolation structure at one side of a base plate, the isolation structure encircling a plurality of isolation openings; forming a first light-emitting material layer, a first encapsulation material layer, and an optical functional material layer in sequence at one side of the base plate; and removing a portion of the optical functional material layer, and removing the first encapsulation material layer and the first light-emitting material layer located at locations corresponding to a portion of the isolation openings, so as to form a first light-emitting structure and a first encapsulation portion at locations corresponding to the others of the isolation openings and form an optical functional portion; in which the first light-emitting structure and the first encapsulation portion are arranged corresponding to the isolation opening, and an orthographic projection of the optical functional portion on the base plate overlaps an orthographic projection of at least one of the first light-emitting structure or the isolation structure on the base plate.

In some embodiments, after the removing the portion of the optical functional material layer, and removing the first encapsulation material layer and the first light-emitting material layer located at locations corresponding to the portion of the isolation openings, the method further comprises:

thinning the second adjustment portion, so that a surface of the second adjustment portion away from the base plate is parallel to a plane in which the base plate is located.

The embodiments of the present application provide the display panel, the display apparatus, and the method for manufacturing the display panel. The presence of the optical functional portion can improve the use experience of the display panel, and the optical functional portion is arranged in the encapsulation protection layer. With such design, no new film layer structure for arranging the optical functional portion is required for the display panel, so that the overall thickness of the display panel will not be affected while the use experience of the display panel can be improved, which facilitates the light and thin design of the display panel.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be obtained based on these drawings without inventive effort.

FIG. 1 shows a schematic sectional structural diagram of a display panel according to an embodiment of the present application;

FIG. 2 shows a schematic sectional structural diagram of another display panel according to an embodiment of the present application;

FIG. 3 shows a schematic sectional structural diagram of yet another display panel according to an embodiment of the present application;

FIG. 4 shows an enlarged schematic structural diagram at an area Q in FIG. 3;

FIG. 5 shows a schematic partial sectional diagram of yet another display panel according to an embodiment of the present application;

FIG. 6 shows a schematic sectional structural diagram of yet another display panel according to an embodiment of the present application;

FIG. 7 shows an enlarged schematic structural diagram at an area P in FIG. 6;

FIG. 8 shows a schematic partial sectional diagram of yet another display panel according to an embodiment of the present application;

FIG. 9 shows a schematic sectional structural diagram of yet another display panel according to an embodiment of the present application;

FIG. 10 shows a schematic structural diagram of a display apparatus according to an embodiment of the present application;

FIG. 11 shows a flowchart of a method for manufacturing a display panel according to an embodiment of the present application;

FIGS. 12A to 12C show schematic process structural diagrams of a method for manufacturing a display panel according to an embodiment of the present application;

FIG. 13 shows a flowchart of a method for manufacturing a display panel according to an embodiment of the present application;

FIG. 14 shows a schematic process structural diagram of a method for manufacturing a display panel according to an embodiment of the present application;

FIG. 15 shows a flowchart of a method for manufacturing a display panel according to an embodiment of the present application;

FIG. 16 shows a schematic process structural diagram of a display panel according to an embodiment of the present application;

FIG. 17 shows a flowchart of a method for manufacturing a display panel according to an embodiment of the present application;

FIG. 18 shows a schematic structural diagram of a display panel according to an embodiment of the present application;

FIG. 19 shows a schematic process structural diagram of another display panel according to an embodiment of the present application;

FIG. 20 shows a flowchart of a method for manufacturing a display panel according to an embodiment of the present application;

FIGS. 21A to 21B show schematic process structural diagrams of a method for manufacturing a display panel according to an embodiment of the present application.

### REFERENCE NUMERALS

10, base plate;
20, isolation structure; 21, isolation opening; 22, first isolation portion; 23, second isolation portion; 24, third isolation portion;
30, light-emitting functional layer; 31, light-emitting structure; 31a, first light-emitting structure; 31b, second light-emitting structure;
40, encapsulation protection layer; 41, first encapsulation layer; 411, first encapsulation portion; 42, second encapsulation layer; 43, third encapsulation layer;
50, optical functional portion; 51, first adjustment portion; 52, second adjustment portion;
60, first electrode layer; 61, first electrode;
70, second electrode layer; 71, second electrode;
50′, optical functional material layer; 52′, second adjustment material layer; 411′, first encapsulation material layer; 31a′, first light-emitting material layer; 31b′, second light-emitting material layer;
B1, first portion; B2, second portion; B3, third portion; B4, fourth portion;
A, gap space;
X, thickness direction.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely configured to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device comprising/including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes these elements.

With the development of informatization, the field of display panel has been rapidly developed, and people's requirement for the display panel is higher and higher. However, how to improve the display effect and thin/light performance of the display panel while reducing the cost of manufacturing the display panel has become the research direction of many manufacturers.

In a first aspect, referring to FIG. 1, the embodiments of the present application provide a display panel. The display panel includes a base plate 10, an isolation structure 20, a light-emitting functional layer 30, an encapsulation protection layer 40, and an optical functional portion 50. The isolation structure 20 is arranged at one side of the base plate 10 and encircles a plurality of isolation openings 21. The light-emitting functional layer 30 is arranged at one side of the base plate 10 and includes a light-emitting structure 31 arranged corresponding to the isolation opening 21.

The encapsulation protection layer 40 is arranged at a side of the light-emitting functional layer 30 away from the base plate 10 and is partially embedded in the isolation opening 21. The optical functional portion 50 is arranged in the encapsulation protection layer, an orthographic projection of the optical functional portion 50 on the base plate 10 overlaps an orthographic projection of at least one of the isolation structure 20 or the light-emitting structure 31 on the base plate 10.

The base plate 10 is mainly configured to provide support, and other film layers are stacked in sequence on the base plate 10. The “stacked” herein means that other film layers are arranged in sequence along a thickness direction of the base plate 10, in which the base plate 10 may include a plurality of film layers, and the specific structure of the film layers is not limited in the embodiments of the present application. In addition, a thickness direction of other film layers located at one side of the base plate 10 is generally the same as the thickness direction of the base plate 10, and thus for the convenience of description, the thickness direction of the base plate 10 or the thickness direction of other film layers mentioned subsequently in the embodiments of the present application are both illustrated as the same direction.

The light-emitting functional layer 30 and the isolation structure 20 are located at the same side of the base plate 10, and the light-emitting functional layer 30 includes the light-emitting structure 31 arranged corresponding to the isolation opening 21. “The light-emitting structure 31 arranged corresponding to the isolation opening 21” herein means that an orthographic projection of the light-emitting structure 31 on the base plate 10 is at least partially located within an orthographic projection of the isolation opening 21 on the base plate 10. Herein, the light-emitting structure 31 may be located at least partially in the isolation opening 21, or may be located at least partially at a side of the isolation opening 21 facing the base plate 10, which is not limited in the embodiments of the present application.

The light-emitting structure 31 includes, but is not limited to, a red light-emitting structure configured to emit red light, a green light-emitting structure configured to emit green light, and a blue light-emitting structure configured to emit blue light. Each light-emitting structure 31 may include a hole inject layer (HIL), a hole transport layer (HTL), a light-emitting layer, an electron inject layer (EIL), an electron transport layer (ETL), and other film layers that are stacked. In some other embodiments, the light-emitting structure 31 may include a plurality of light-emitting layers that are stacked, and a charge generation layer is provided between adjacent light-emitting layers.

With the isolation structure 20, the light-emitting functional layer 30 can form a plurality of light-emitting structures 31 arranged at intervals without a fine metal mask plate, so as to reduce the cost of manufacturing the display panel. Specifically, in an example where the red light-emitting structure is manufactured before the green light-emitting structure, since the fine metal mask plate is omitted, the red light-emitting material corresponding to the red light-emitting structure first falls into the isolation openings 21, then the red light-emitting material in a portion of the isolation openings 21 is selectively etched and removed, and the red light-emitting material in a portion of the isolation openings 21 is kept, so as to form the red light-emitting structure. Next, the green light-emitting material corresponding to the green light-emitting structure falls into the isolation openings 21, then the green light-emitting material in a portion of the isolation openings 21 is selectively etched and removed, and the green light-emitting material in a portion of the isolation openings 21 is kept, so as to form the green light-emitting structure.

The encapsulation protection layer 40 is located at the side of the light-emitting functional layer 30 away from the base plate 10, and may be configured to encapsulate and protect the light-emitting functional layer 30 to reduce the effect of factors such as water vapor on the light-emitting structure 31. Furthermore, the encapsulation protection layer 40 may be partially embedded in the isolation opening 21 due to the isolation structure 20, and the light-emitting structure 31 is generally arranged corresponding to the isolation opening 21, so that a portion of the encapsulation protection layer 40 embedded in the isolation opening 21 can independently encapsulate the light-emitting structure 31, so as to further reduce the effect of factors such as water vapor on the light-emitting structure 31, thereby improving the use reliability of the display panel.

In addition, the display panel according to the embodiments of the present application further includes the optical functional portion 50 which can adjust light. According to different actual use situations, the light mentioned herein may include both the light emitted from the light-emitting structure 31 and the light entering the interior of the display panel from the external environment, which is not limited in the embodiments of the present application, as long as the optical functional portion 50 can adjust at least a portion of the light to improve the use experience of the display panel.

Further, the position of the optical functional portion 50 may be different according to different use requirements. Specifically, the optical functional portion 50 may be selectively arranged overlapping only the orthographic projection of the light-emitting structure 31 on the base plate 10, or the optical functional portion 50 may be selectively arranged overlapping only the orthographic projection of the isolation structure 20 on the base plate 10, or the optical functional portion 50 may be selectively arranged overlapping both the orthographic projection of the light-emitting structure 31 on the base plate 10 and the orthographic projection of the isolation structure 20 on the base plate 10.

In the related art, the optical functional portion 50 is generally located at the position of the display panel close to the light-emitting surface, i.e. in the thickness direction, a greater spacing is generally formed between the optical functional portion 50 and the light-emitting functional layer 30. However, under this design, the presence of the optical functional portion 50 may increase the overall thickness corresponding to the display panel, which is not beneficial for the light and thin configuration of the display panel.

However, in the embodiments of the present application, the presence of the optical functional portion 50 can improve the use experience of the display panel, and the optical functional portion 50 is arranged in the encapsulation protection layer 40. With such design, no new film layer structure for arranging the optical adjustment portion 50 is required for the display panel, so that the overall thickness of the display panel will not be affected while the use experience of the display panel can be improved, which facilitates the light and thin design of the display panel.

Note that the encapsulation protection layer 40 may include a plurality of film layer structures that are stacked, in which the optical functional portion 50 may be selectively arranged between any two film layer structures in the encapsulation protection layer 40. In addition, under a condition that the optical functional portion 50 includes different structures, the different structures in the optical functional portion 50 may be respectively arranged at different heights of the encapsulation protection layer 40 in the thickness direction, or may be arranged at the same height of the encapsulation protection layer 40 in the thickness direction, which is not limited in the embodiments of the present application.

In some embodiments, as shown in FIG. 1, the encapsulation protection layer 40 includes a first encapsulation layer 41, a second encapsulation layer 42, and a third encapsulation layer 43 that are stacked in sequence along a direction away from the base plate 10; and the first encapsulation layer 41 includes a plurality of first encapsulation portions 411 respectively arranged in the plurality of isolation openings 21.

The encapsulation protection layer 40 includes at least three film layers, i.e., the first encapsulation layer 41, the second encapsulation layer 42, and the third encapsulation layer 43, and the three film layers collectively form a thin film encapsulation structure, thereby facilitating improving the encapsulation protection effect of the encapsulation protection layer 40 on the light-emitting structure 31. Materials of the first encapsulation layer 41, the second encapsulation layer 42, and the third encapsulation layer 43 are not limited in the embodiments of the present application. Optionally, the first encapsulation layer 41 and the third encapsulation layer 43 include an inorganic material, and the second encapsulation layer 42 includes an organic material, so that the first encapsulation layer 41 and the third encapsulation layer 43 can limit the second encapsulation layer 42 while satisfying the encapsulation requirements.

Further, the first encapsulation layer 41 is a film layer closest to the light-emitting structure 31 in the encapsulation protection layer 40, in which the first encapsulation layer 41 may include a plurality of first encapsulation portions 411 respectively arranged in the plurality of isolation openings 21, and the plurality of first encapsulation portions 411 may be arranged corresponding to the plurality of light-emitting structures 31, so as to independently encapsulate the plurality of light-emitting structures 31, thereby improving the encapsulation reliability.

The specific positional relationship of the optical functional portion 50 with respect to the encapsulation protection layer 40 is not limited in the embodiments of the present application. Exemplarily, in the thickness direction, at least a portion of the optical functional portion 50 may be sandwiched between any two layers of the encapsulation protection layer 40, or at least a portion of the optical functional portion 50 may be arranged inside at least one of the first encapsulation layer 41, the second encapsulation layer 42, or the third encapsulation layer 43.

It should be noted that, in addition to the thickness direction, in a direction parallel to a plane in which the base plate 10 is located, the position of the optical functional portion 50 may also be set in various manners. For example, the optical functional portion 50 may be arranged corresponding to the first encapsulation portion 411, i.e., an orthographic projection of the optical functional portion 50 on the base plate 10 overlaps an orthographic projection of the first encapsulation portion 411 on the base plate 10, and the optical functional portion 50 is arranged in contact with the first encapsulation portion 411. Alternatively, the plurality of first encapsulation portions 411 in the first encapsulation layer 41 are arranged at intervals, and the optical functional portion 50 may be correspondingly arranged between adjacent first encapsulation portions 411, i.e., the optical functional portion 50 is arranged in the same layer as the first encapsulation portion 411.

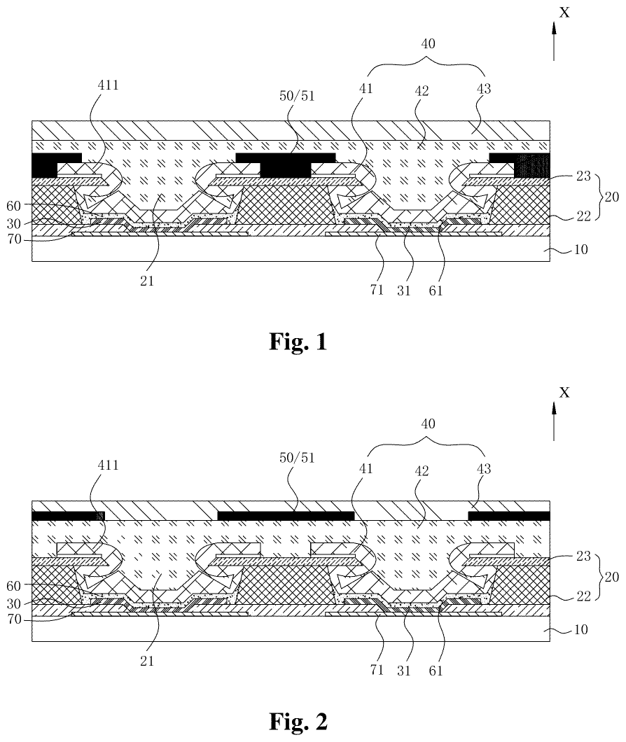

In some optional embodiments, as shown in FIG. 1, the optical functional portion 50 is at least partially located between the first encapsulation layer 41 and the second encapsulation layer 42. In some other embodiments, as shown in FIG. 2, the optical functional portion 50 may be at least partially located between the second encapsulation layer 42 and the third encapsulation layer 43.

In some embodiments, the isolation structure 20 includes a first isolation portion 22 and a second isolation portion 23 that are stacked in sequence along a direction away from the base plate 10, and an orthographic projection of the first isolation portion 22 on the base plate 10 is located within an orthographic projection of the second isolation portion 23 on the base plate 10.

The specific sizes and shapes of the first isolation portion 22 and the second isolation portion 23 are not limited in the embodiments of the present application. Exemplarily, a longitudinal section of the isolation structure 20 may be T-shaped. In the manufacturing process of the light-emitting functional layer 30, such design makes it difficult for the light-emitting material to extend along a sidewall of the first isolation portion 22 to a sidewall of the second isolation portion 23, so as to manufacture and separate the light-emitting structures 30 corresponding to different isolation openings 21 without a fine metal mask plate.

The materials of the first isolation portion 22 and the second isolation portion 23 are not limited in the embodiments of the present application. Both the first isolation portion 22 and the second isolation portion 23 may include an electrically conductive material, or the first isolation portion 22 includes an electrically conductive material and the second isolation portion 23 includes an electrically insulating material, or both the first isolation portion 22 and the second isolation portion 23 may include an electrically insulating material.

Further, in some embodiments, the display panel further includes a first electrode layer 60 arranged at the side of the light-emitting functional layer 30 away from the base plate 10, and the first electrode layer 60 includes a first electrode 61 arranged corresponding to the isolation opening 21. The first isolation portion 22 includes an electrically conductive material, and the first electrode 61 is electrically connected with the first isolation portion 22.

The first electrode 61 in the first electrode layer 60 is configured to drive and control the light-emitting structure 31 to, or not to, emit light. Optionally, the display panel further includes a second electrode layer 70 arranged at a side of the light-emitting functional layer 30 facing the base plate 10. The first electrode layer 60 and the second electrode layer 70 are respectively arranged at two sides of the light-emitting functional layer 30 in the thickness direction, the second electrode layer 70 includes a plurality of second electrodes 71, and the first electrode 61 and the second electrode 71 cooperate to drive and control the light-emitting structure 31. Herein, the first electrode 61 may be a cathode, and the second electrode 71 may be an anode.

In the related art, the first electrode 61 is generally a planar electrode, and its orthographic projection on the base plate 10 may cover all of the light-emitting structures 31 simultaneously. However, in the embodiments of the present application, the isolation structure 20 may separate the different first electrodes 61 corresponding to at least a portion of different light-emitting structures 31 in the manufacturing process of the display panel, so that the first electrode layer 60 includes a plurality of first electrodes 61, and the first electrode 61 is arranged corresponding to the isolation opening 21.

It should be noted that “the first electrode 61 is arranged corresponding to the isolation opening 21” mentioned in the embodiments of the present application means that: an orthographic projection of the first electrode 61 on the base plate 10 at least partially overlaps the orthographic projection of the isolation opening 21 on the base plate 10. Herein, the first electrode 61 may be entirely located in the isolation opening 21, or the first electrode 61 may be partially located in the isolation opening 21. Further, one first electrode 61 may be arranged corresponding to one light-emitting structure 31, i.e., an orthographic projection of a single first electrode 61 on the base plate 10 only overlaps an orthographic projection of one light-emitting structure 31 on the base plate 10; or a single first electrode 61 may be arranged corresponding to a plurality of light-emitting structures 31 simultaneously, i.e., the orthographic projection of the single first electrode 61 on the base plate 10 overlaps the orthographic projections of the plurality of light-emitting structures 31 on the base plate 10 simultaneously.

Further, the first isolation portion 22 includes an electrically conductive material, and the first electrode 61 may be electrically connected with the first isolation portion 22, so as to transmit signals and satisfy the requirement for controlling the light-emitting structure 31 to, or not to, emit light. Herein, the first electrode 61 may directly contact the first isolation portion 22 to achieve the electrical connection between them, or the first electrode 61 may be electrically connected with the first isolation portion 22 through other electrically conductive structures, which is not limited in the embodiments of the present application.

In the embodiments of the present application, the first electrode layer 60 includes a plurality of first electrodes 61, which may transmit signals by means of the first isolation portion 22. On this basis, the first isolation portion 22 may be adjusted so as to achieve the electrical connection or insulation between different first electrodes 61, thereby satisfying the requirement for divisionally or independently controlling different light-emitting structures 31, which provides higher practicality and flexibility.

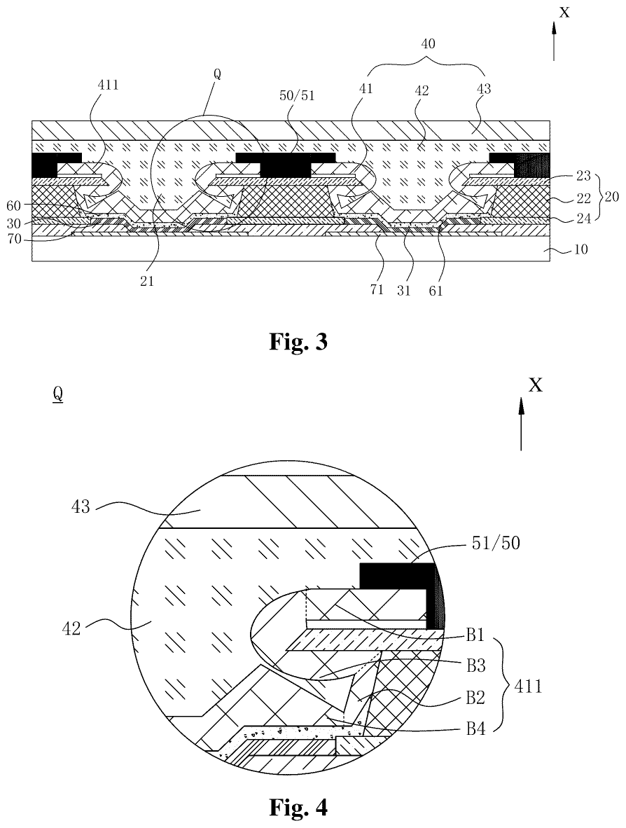

In some embodiments, referring to FIG. 3, the isolation structure 20 further includes a third isolation portion 24 arranged at a side of the first isolation portion 22 facing the base plate 10, and the third isolation portion 24 includes an electrically conductive material and is electrically connected with the first isolation portion 22. Herein, the orthographic projection of the first isolation portion 22 on the base plate 10 is located within an orthographic projection of the third isolation portion 24 on the base plate 10, and the first electrode 61 contacts the third isolation portion 24.

In addition to the first isolation portion 22 and the second isolation portion 23, the isolation structure 20 may further include the third isolation portion 24, and the third isolation portion 24 is arranged closer to the base plate 10 than the first isolation portion 22 and the second isolation portion 23. Moreover, an area of the orthographic projection of the third isolation portion 24 on the base plate 10 can be greater than an area of the orthographic projection of the first isolation portion 22 on the base plate 10, so that the first electrode 61 contacts the third isolation portion 24 more easily, i.e., the first electrode 61 can contact the third isolation portion 24. Specifically, a portion of the first electrode 61 may be arranged covering the third isolation portion 24.

On this basis, in the embodiments of the present application, the third isolation portion 24 includes an electrically conductive material and is electrically connected with the first isolation portion 22. In this way, the electrical connection between the first electrode 61 and the first isolation portion 22 may be achieved through the third isolation portion 24, so as to improve the reliability of the electrical connection between the first electrode 61 and the first isolation portion 22 and satisfy the requirement for signal transmission inside the first electrode 61.

In some embodiments, as shown in FIGS. 1 to 3, the optical functional portion 50 includes a first adjustment portion 51 arranged at a side of the second isolation portion 23 away from the base plate 10, and a light reflectivity corresponding to the first adjustment portion 51 is less than a light reflectivity corresponding to the second isolation portion 23.

The second isolation portion 23 may have various material compositions according to different use situations, and under the effect of certain materials, the second isolation portion 23 may have a higher light reflectivity. Under this condition, the ambient light from the outside reaches the second isolation portion 23, and then is reflected by the second isolation portion 23 to be emitted out, together with the light emitted by the light-emitting structure 31, towards the light-emitting surface of the display panel. In this way, the ambient light reflected by the second isolation portion 23 may affect the display effect of the display panel to some extent.

In view of this, in the embodiments of the present application, the first adjustment portion 51 is added at the side of the second isolation portion 23 away from the base plate 10, and the first adjustment portion 51 may cover at least a portion of the surface of the second isolation portion 23 away from the base plate 10. Further, the first adjustment portion 51 has a lower light reflectivity than the second isolation portion 23. Therefore, the presence of the first adjustment portion 51 can reduce the reflection of the ambient light at the isolation structure 20, thereby facilitating improving the display effect of the display panel.

In some embodiments, the first adjustment portion 51 may cover the entire surface of the second isolation portion 23 away from the base plate 10, or the first adjustment portion 51 may cover only a portion of the surface of the second isolation portion 23 away from the base plate 10. Optionally, an orthographic projection of the first adjustment portion 51 on the base plate 10 covers the orthographic projection of the second isolation portion 23 on the base plate 10.

Further optionally, the orthographic projection of the first adjustment portion 51 on the base plate 10 covers the orthographic projection of the second isolation portion 23 on the base plate 10 and at least a portion of the light-emitting structure 31. In addition, the material of the first adjustment portion 51 is not limited in the embodiments of the present application. The first adjustment portion 51 may include an electrically conductive material or an electrically insulating material, as long as the light reflectivity corresponding to the first adjustment portion 51 is lower than the light reflectivity corresponding to the second isolation portion 23. Optionally, the first adjustment portion 51 may include a light-absorbing material, such as a black matrix, i.e., a black electrically insulating material. The black matrix helps to absorb more ambient light than other materials, thereby further reducing the reflection of the ambient light in the display panel.

In some embodiments, referring to FIGS. 3 and 4, the encapsulation protection layer 40 includes a first encapsulation layer 41, a portion of the first encapsulation layer 41 is arranged in contact with the isolation structure 20, the first encapsulation layer 41 includes a first portion B1 located at the side of the second isolation portion 23 away from the base plate 10, and the first adjustment portion 51 is at least partially located at a side of the first portion B1 away from the base plate 10 and arranged in contact with the first portion B1.

From the above description, the encapsulation protection layer 40 may include a plurality of film layer structures that are stacked, in which the first encapsulation layer 41 is located in a film layer of the encapsulation protection layer 40 that is closest to the base plate 10. In the manufacturing process of the first encapsulation layer 41, due to the isolation structure 20, the first encapsulation layer 41 may include a plurality of first encapsulation portions 411 arranged corresponding to the plurality of isolation openings 21, the first encapsulation portion 411 may be arranged in contact with the isolation structure 20, and a portion of the first encapsulation portion 411 may extend to the side of the second isolation portion 23 away from the base plate 10 to form the first portion B1.

On this basis, the first adjustment portion 51 is at least partially located at the side of the first portion B1 away from the base plate 10 and is arranged in contact with the first portion B1. That is, the first adjustment portion 51 may be at least partially located between the first encapsulation layer 41 and the second encapsulation layer 42, so that the first adjustment portion 51 can be formed after the first encapsulation layer 41 is manufactured, thereby reducing the effect of the first adjustment portion 51 on the manufacturing of the first encapsulation layer 41.

In addition, under this design, the first adjustment portion 51 is closer to the light-emitting functional layer 30, so that the first adjustment portion 51 helps to absorb more lateral light emitted by the surrounding light-emitting structures 31, thereby reducing the risk of light interference among different light-emitting structures 31, which helps to improve the display reliability. Moreover, if the display panel is a flexible display panel, such a design also helps to reduce the risk of cracking of the corresponding film layer upon bending and improve the overall structural reliability.

It should be noted that in the manufacturing process of the light-emitting functional layer 30 and the first electrode layer 60, a portion of the light-emitting material and the electrode material (not shown in the figures), etc., may fall to the side of the second isolation portion 23 away from the base plate 10, which results in the existence of a portion of the light-emitting material and the electrode material between the first portion B1 in the subsequently formed first encapsulation portion 411 and the second isolation portion 23, i.e., the first portion B1 and the second isolation portion 23 may be spaced apart from each other.

In some embodiments, the isolation structure 20 encircles two or more isolation openings 21, the first encapsulation layer 41 includes a plurality of first encapsulation portions 411 arranged corresponding to the two or more isolation openings 21, and first portions B1 corresponding to at least a portion of adjacent first encapsulation portions 411 are spaced apart. Herein, the first adjustment portion 51 is at least partially located between adjacent first portions B1.

Due to the isolation structure 20, the first encapsulation layer 41 may include a plurality of first encapsulation portions 411 arranged corresponding to the two or more isolation openings 21 and spaced apart from each other, and specifically, a certain spacing may be formed between two adjacent first portions B1 in adjacent first encapsulation portions 411.

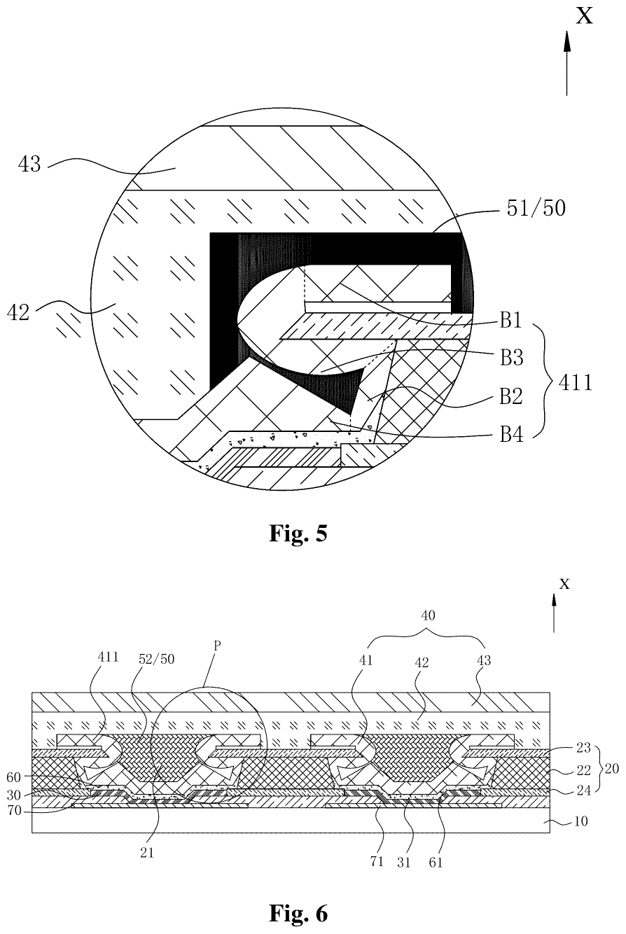

On this basis, the first adjustment portion 51 may be partially located between the adjacent first portions B1, which helps to enable the first adjustment portion 51 to cover more area on the second isolation portion 23, thereby further reducing the light reflection due to the second isolation portion 23, so as to improve the display effect of the display panel. Optionally, the first adjustment portion 51 may include two portions, in which one portion is located at the side of the first portion B1 away from the base plate 10, and the other portion is located between the adjacent first portions B1. Further, as shown in FIG. 5, a portion of the first adjustment portion 51 may be located at the same height as the first isolation portion 22 in the thickness direction of the base plate 10.

In some embodiments, referring to FIG. 6, the optical functional portion 50 includes a plurality of second adjustment portions 52, and the second adjustment portion 52 is at least partially embedded in the isolation opening 21 and includes a color filter.

Since the second adjustment portion 52 is at least partially embedded in the isolation opening 21, and the light-emitting structure 31 is arranged corresponding to the isolation opening 21, an orthographic projection of the second adjustment portion 52 on the base plate 10 and the orthographic projection of the isolation opening 21 on the base plate 10 can form an overlapping area. Further, at least a portion of the light emitted by the light-emitting structure 31 can reach the isolation opening 21.

On this basis, the second adjustment portion 52 can adjust the light generated by the light-emitting structure 31, thereby helping to improve the display effect of the display panel. Herein, the second adjustment portion 52 may have various forms, and further, the second adjustment portion 52 may include a color filter capable of filtering the light generated by the light-emitting structure 31, thereby improving the display accuracy of the display panel. For example, the color filter may be a red color filter, a blue color filter, or a green color filter. Alternatively, in some other embodiments, the second adjustment portion 52 may include a high refractive index material or a low refractive index material, so as to change the angle of emergence of the light generated by the light-emitting structure 31, thereby increasing or reducing the observable angle of the display panel to achieve the observation at a large viewing angle or improve the privacy.

It should be noted that, according to different use requirements of the display panel, the display panel may include only the first adjustment portion 51, or only the second adjustment portion 52, or both the first adjustment portion 51 and the second adjustment portion 52, which is not limited in the embodiments of the present application.

In some embodiments, the second adjustment portion 52 includes a first surface at a side away from the base plate 10, and the first surface is parallel to a plane in which the base plate 10 is located.

In the embodiments of the present application, the surface of the second adjustment portion 52 at the side away from the base plate 10 may be planarized through a nano-fabrication technique, an ashing process, etc., so that the first surface is parallel to the plane in which the base plate 10 is located. This helps to improve the surface flatness of the second adjustment portion 52, thereby reducing the difficulty in manufacturing other film layers after the second adjustment portion 52. Further optionally, the first surface is the same height as a surface of the first portion B1 away from the base plate 10.

In some embodiments, the encapsulation protection layer 40 includes the first encapsulation layer 41, and the first encapsulation layer 41 includes a plurality of first encapsulation portions 411 respectively arranged in the isolation openings 21, and the second adjustment portion 52 is located at a side of the first encapsulation portion 411 away from the base plate 10.

The second adjustment portion 52 is partially located at the side of the first encapsulation portion 411 away from the base plate 10. Herein, the second adjustment portion 52 may be arranged in contact with the first encapsulation portion 411, or the second adjustment portion 52 may be spaced apart from the first encapsulation portion 411 in the thickness direction, which is not limited in the embodiments of the present application.

In the embodiments of the present application, the second adjustment portion 52 may be located at the side of the first encapsulation portion 411 away from the base plate 10, so that the second adjustment portion 52 may be formed after the first encapsulation layer 41 is manufactured, thereby reducing the effect of the second adjustment portion 52 on the manufacturing of the first encapsulation layer 41. Further optionally, the second adjustment portion 52 is arranged in contact with the first encapsulation portion 411.

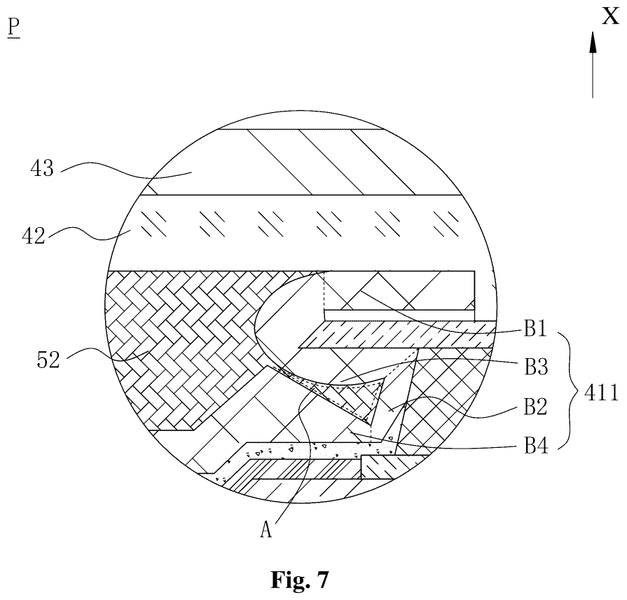

Further, referring to FIGS. 6 and 7, in some embodiments, the isolation structure 20 includes a first isolation portion 22 and a second isolation portion 23 that are stacked in sequence along a direction away from the base plate 10, and an orthographic projection of the first isolation portion 22 on the base plate 10 is located within an orthographic projection of the second isolation portion 23 on the base plate 10.

The first encapsulation portion 411 includes a second portion B2 arranged in contact with the first isolation portion 22, a third portion B3 arranged in contact with the second isolation portion 23, and a fourth portion B4 connected with the second portion B2 and covering the light-emitting structure 31. The third portion B3 and the fourth portion B4 are spaced apart in the thickness direction to form a gap space A, and the second adjustment portion 52 is at least partially located at a side of the gap space A away from the base plate 10.

The first encapsulation portion 411 may include the first portion B1, the second portion B2, the third portion B3, and the fourth portion B4, in which the fourth portion B4 is arranged covering the light-emitting structure 31, the second portion B2 is arranged in contact with the first isolation portion 22 and is connected with the fourth portion B4, the third portion B3 is arranged in contact with the second isolation portion 23 and is connected with the second portion B2, and the first portion B1 is located at the side of the second isolation portion 23 away from the base plate 10 and is connected with the third portion B3.

Referring to FIG. 6, the gap space A is formed between the third portion B3 and the fourth portion B4, and thus the first encapsulation portion 411 may be etched due to the existence of the gap space A. Specifically, for example, the red light-emitting structure is manufactured before the green light-emitting structure. In the manufacturing process, the red light-emitting structure and a first electrode 61 and a first encapsulation portion 411 that correspond to the red light-emitting structure are firstly formed in the isolation openings 21, and then the red light-emitting structure and the first electrode 61 and the first encapsulation portion 411 that correspond to the red light-emitting structure located at locations corresponding to a portion of the isolation openings 21 are selectively removed. Then, the green light-emitting structure and a first electrode 61 and a first encapsulation portion 411 that correspond to the green light-emitting structure are formed in the isolation openings 21, and thus the red light-emitting structure, the green light-emitting structure, the first electrode 61 and the first encapsulation portion 411 that correspond to the red light-emitting structure, and the first electrode 61 and the first encapsulation portion 411 that correspond to the green light-emitting structure are provided simultaneously at locations corresponding to a portion of isolation openings 21. Finally, the green light-emitting structure and the first electrode 61 and the first encapsulation portion 411 that correspond to the green light-emitting structure located at locations corresponding to a portion of isolation openings 21 are selectively removed.

However, in the process of removing the green light-emitting structure, since the red light-emitting structure and the green light-emitting structure are provided simultaneously at locations corresponding to a portion of isolation openings 21, the etching gas for removing the first encapsulation portion 411 located at a side of the green light-emitting structure away from the base plate 10 is likely to invade into the gap space A and likely to etch and remove a portion of the first encapsulation portion 411 corresponding to the red light-emitting structure, and even a portion of the first electrode 61 covered by the first encapsulation portion 411 corresponding to the red light-emitting structure is exposed in severe cases. On this basis, in the process of removing the green light-emitting structure using a wet process, the chemicals may invade into the gap space A and contact the first electrode 61, and thus affect the structural reliability of the first electrode 61.

On this basis, the second adjustment portion 52 in the embodiments of the present application can adjust light, and further, since at least a portion of the second adjustment portion 52 is arranged at the side of the gap space A away from the base plate 10, i.e., the second adjustment portion 52 may be arranged covering the gap space A, the second adjustment portion 52 can also reduce, in the manufacturing process, the probability of the etching gas, the chemicals, etc. invading into the gap space A, so as to reduce the risk of damaging the first encapsulation portion 411 and the first electrode 61 and improve the yield and overall reliability of the display panel.

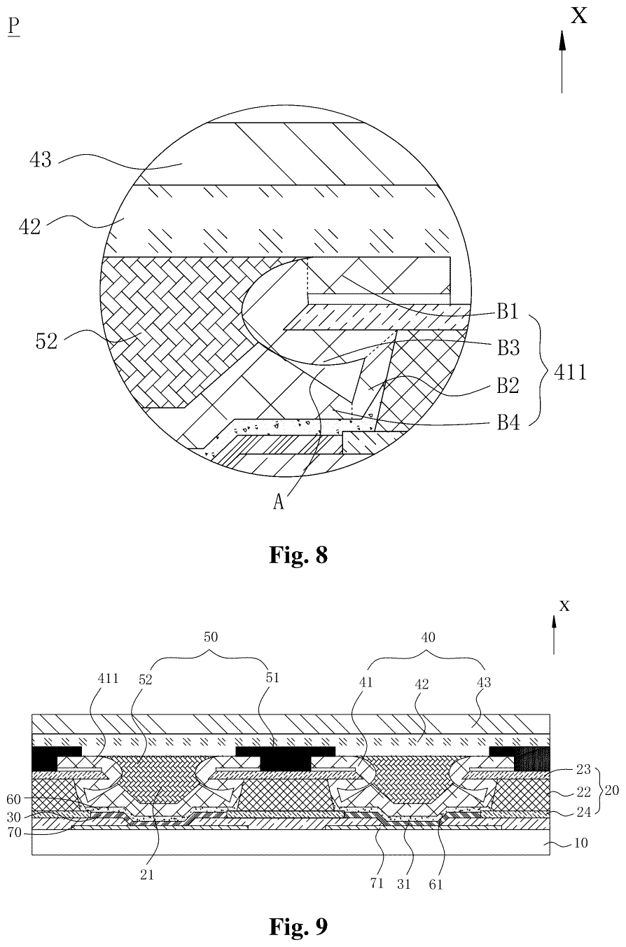

It should be noted that, according to different actual manufacturing situations, the second adjustment portion 52 may be partially located within the gap space, or the second adjustment portion 52 may be located entirely outside the gap space A. Specifically, according to different sizes of the isolation structure 20 in the thickness direction of the base plate 10, the third portion B3 and the fourth portion B4 in the subsequently formed first encapsulation layer 41 may be connected as one piece or spaced apart from each other. As shown in FIG. 8, under a condition that the third portion B3 and the fourth portion B4 are connected as one piece, the second adjustment portion 52 cannot enter into the gap space A, so as to be located entirely at the side of the gap space away from the base plate 10. As shown in FIG. 7, under a condition that the third portion B3 is spaced apart from the fourth portion B4, the second adjustment portion 52 may partially enter into the gap space A. Optionally, the second adjustment portion 52 is partially located within the gap space A.

In addition, referring to FIG. 5, if the display panel includes the first adjustment portion 51, and the orthographic projection of the first adjustment portion 51 on the base plate 10 covers a portion of the orthographic projection of the light-emitting structure 31 on the base plate 10, the first adjustment portion 51 also helps to prevent the etching gas, the chemicals, etc., from invading into the gap space A, so as to reduce the risk of damaging the first encapsulation portion 411 and the first electrode 61 and improve the yield and overall reliability of the display panel.

In some embodiments, referring to FIG. 9, the optical functional portion 50 further includes a first adjustment portion 51, and an orthographic projection of the first adjustment portion 51 on the base plate 10 is at least partially located between orthographic projections of adjacent second adjustment portions 52 on the base plate 10. Herein, the first regulation portion 51 includes a light-absorbing material, and preferably, may include a black matrix.

In the embodiments of the present application, the optical functional portion 50 includes both the first adjustment portion 51 and the second adjustment portion 52, and the orthographic projection of the first adjustment portion 51 on the base plate 10 and the orthographic projection of the second adjustment portion 52 on the base plate 10 may partially overlap or not overlap. The second adjustment portion 52 is arranged corresponding to the light-emitting structure 31, and the second adjustment portion 52 may adjust at least a portion of the light emitted by the light-emitting structure 31 to improve the display effect of the display panel. The first adjustment portion 51 may be arranged corresponding to the second isolation portion 23 in the isolation structure 20, and the first adjustment portion 51 includes a light-absorbing material, and thus the first adjustment portion 51 can absorb at least a portion of the external ambient light reaching the second isolation portion 23, thereby reducing the light reflection corresponding to the second isolation portion 23, which also helps to improve the display effect of the display panel.

Further, the specific positional relationship between the first adjustment portion 51 and the second adjustment portion 52 is not limited in the embodiments of the present application. Optionally, as shown in FIG. 9, the encapsulation protection layer 40 includes a second encapsulation layer 42 located at a side of the first encapsulation layer 41 away from the base plate 10, and both the first adjustment portion 51 and the second adjustment portion 52 are at least partially located between the first encapsulation layer 41 and the second encapsulation layer 42.

With such design, both the first adjustment portion 51 and the second adjustment portion 52 can be manufactured after the first encapsulation layer 41, thereby reducing the effect of the first adjustment portion 51 and the second adjustment portion 52 on the manufacturing process of the first encapsulation layer 41. Moreover, since both the first adjustment portion 51 and the second adjustment portion 52 are at least partially located between the first encapsulation layer 41 and the second encapsulation layer 42, the first adjustment portion 51 and the second adjustment portion 52 can be respectively manufactured in adjacent manufacturing processes, which helps to improve the reliability of the relative position between them.

In some other embodiments, the second adjustment portion 52 may be located between the first encapsulation layer 41 and the second encapsulation layer 42, while the first adjustment portion 51 is located between the second encapsulation layer 42 and the third encapsulation layer 43. Alternatively, in some other embodiments, the first adjustment portion 51 may be located between the first encapsulation layer 41 and the second encapsulation layer 42, while the second adjustment portion 52 is located between the second encapsulation layer 42 and the third encapsulation layer 43.

Further, in some embodiments, the isolation structure 20 includes the first isolation portion 22 and the second isolation portion 23 that are stacked in sequence along the direction away from the base plate 10, and the orthographic projection of the first isolation portion 22 on the base plate 10 is located within the orthographic projection of the second isolation portion 23 on the base plate 10.

The first encapsulation portion 411 includes the second portion B2 arranged in contact with the first isolation portion 22, the third portion B3 arranged in contact with the second isolation portion 23, and the fourth portion B4 connected with the second portion B2 and covering the light-emitting structure 31. The third portion B3 and the fourth portion B4 are spaced apart in the thickness direction to form the gap space A, and the first adjustment portion 51 is at least partially located at the side of the gap space A away from the base plate 10.

The first adjustment portion 51 in the embodiments of the present application can reduce light reflection, and further, since at least a portion of the first adjustment portion 51 is arranged at the side of the gap space A away from the base plate 10, i.e., the first adjustment portion 51 may be arranged covering the gap space A, the first adjustment portion 51 can also reduce, in the manufacturing process, the probability of the etching gas, the chemicals, etc., invading into the gap space A, so as to reduce the risk of damaging the first encapsulation portion 411 and the first electrode 61 and improve the yield and overall reliability of the display panel. Further optionally, the first adjustment portion 51 is partially located within the gap space A.

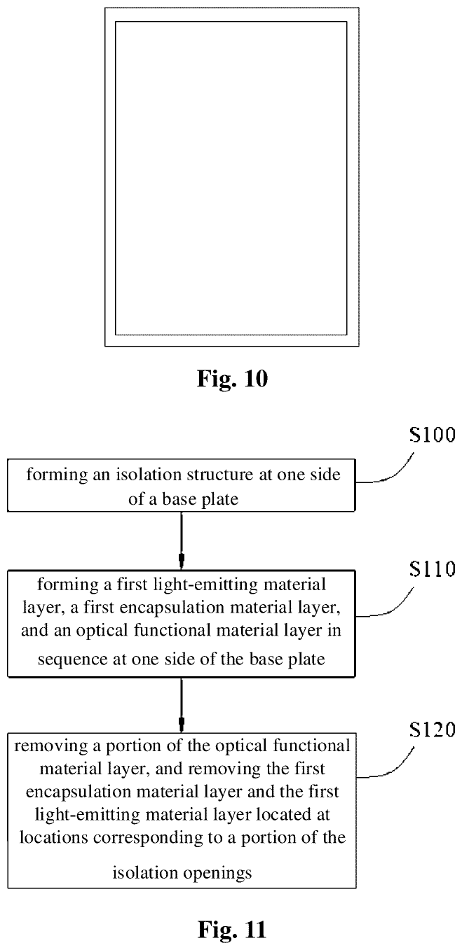

In a second aspect, referring to FIG. 10, the embodiments of the present application provide a display apparatus including the display panel according to any of the above implementations.

It should be noted that the display apparatus according to the embodiments of the present application has the beneficial effects of the display panel according to any of the above implementations, and the details of which are referred to the above description of the display panel and will not repeated in the embodiments of the present application.

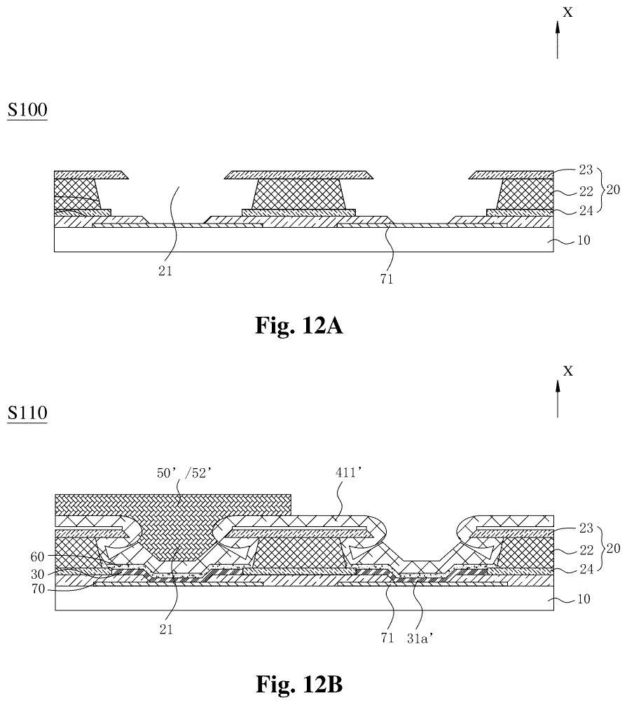

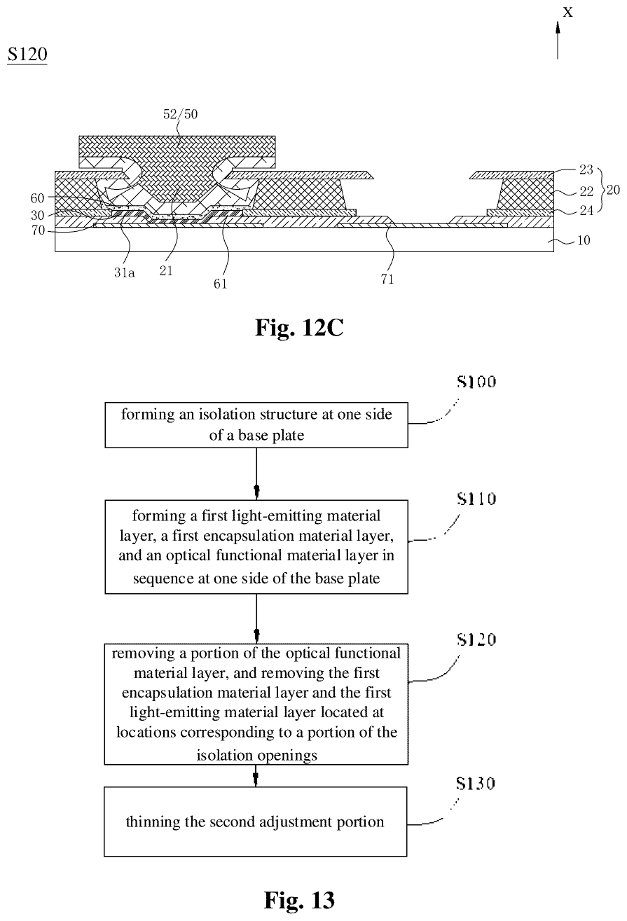

In a third aspect, referring to FIGS. 11 and 12, the embodiments of the present application provide a method for manufacturing a display panel including the following steps.

Step S100: forming an isolation structure at one side of a base plate.

Referring to FIG. 12A, in step S100, the isolation structure 20 encircles a plurality of isolation openings 21, and in subsequent steps, the presence of the isolation structure 20 can achieve the manufacturing of the light-emitting structure and the first electrode without a fine metal mask plate. The structural dimension of the isolation structure 20 is not limited in the embodiments of the present application. Exemplarily, the insulation structure 20 may include a first isolation portion 22, a second isolation portion 23, and a third isolation portion 24 that are stacked.

Step S110: forming a first light-emitting material layer, a first encapsulation material layer, and an optical functional material layer in sequence at one side of the base plate.

Referring to FIG. 12B, in step S110: the first light-emitting material layer 31a′ is configured to form a first light-emitting structure 31a, the first light-emitting structure 31a is a light-emitting structure 31 that is configured to emit light of a particular color; and the optical functional material layer 50′ is configured to form an optical functional portion 50, and the optical functional portion 50 may have various forms, for example, the optical functional portion 50 may be configured to adjust the light emitted by the light-emitting structure 31, or the optical functional portion 50 may be further configured to adjust the external ambient light incident into the display panel. Herein, the optical functional portion 50 may include various structures, for example, the optical functional portion 50 may include a first adjustment portion 51 and a second adjustment portion 52. On this basis, in step S110, only the first adjustment portion 51 may be formed, or only the second adjustment portion 52 may be formed, or both the first adjustment portion 51 and the second adjustment portion 52 may be formed. Herein, the figure illustrates that the optical functional portion 50 includes the second adjustment portion 52.

The first encapsulation material layer 411′ is configured to form a first encapsulation portion 411, both the first light-emitting structure 31a and the first encapsulation portion 411 are arranged corresponding to the isolation opening 21, and an orthographic projection of the optical functional portion 50 on the base plate 10 overlaps an orthographic projection of at least one of the first light-emitting structure 31a or the isolation structure 20 on the base plate 10.

Further, since the optical functional material layer 50′ is located at a side of the first encapsulation material layer away from the base plate 10, the optical functional material layer may protect the first encapsulation material layer to some extent, so as to reduce the risk of etching and removing the portion of the first encapsulation portion 411 that should have been kept in subsequent steps.

Step S120: removing a portion of the optical functional material layer, and removing the first encapsulation material layer and the first light-emitting material layer located at locations corresponding to a portion of the isolation openings.

Referring to FIG. 12C, in step S120, a portion of the optical functional material layer 50′ and the first encapsulation material layer 411′ and the first light-emitting material layer 31a′ located at locations corresponding to a portion of the isolation openings 21 are removed, so as to form a first light-emitting structure 31a, a first encapsulation portion 411, and an optical functional portion 50 at locations corresponding to the others of the isolation openings 21. Herein, the first light-emitting structure 31a and the first encapsulation portion 411 are arranged corresponding to the isolation opening 21, and an orthographic projection of the optical functional portion 50 on the base plate 10 overlaps an orthographic projection of at least one of the first light-emitting structure 31a or the isolation structure 20 on the base plate 10.

In some embodiments, the optical functional material layer includes a second adjustment material layer.

Referring to FIGS. 12B and 12C, in step S120, the first light-emitting material layer 31a′, the first encapsulation material layer 411′, and the second adjustment material layer 52′ located at locations corresponding to the portion of the isolation openings 21 are removed, so as to form the first light-emitting structure 31a, the first encapsulation portion 411, and a second adjustment portion 52 at locations corresponding to the others of the isolation openings, and the second adjustment portion 52 is at least partially located in the isolation opening 21. Optionally, the second adjustment portion 52 includes a color filter.

In the embodiments of the present application, the second adjustment portion 52 can not only adjust light, but also isolate and keep the first light-emitting structure 31a and the first encapsulation portion 411 required to be kept in the manufacturing process of the display panel, so as to satisfy the etching requirements in step S120 without additional sacrificial layers, which helps to simplify the manufacturing process of the display panel and improve the manufacturing efficiency.

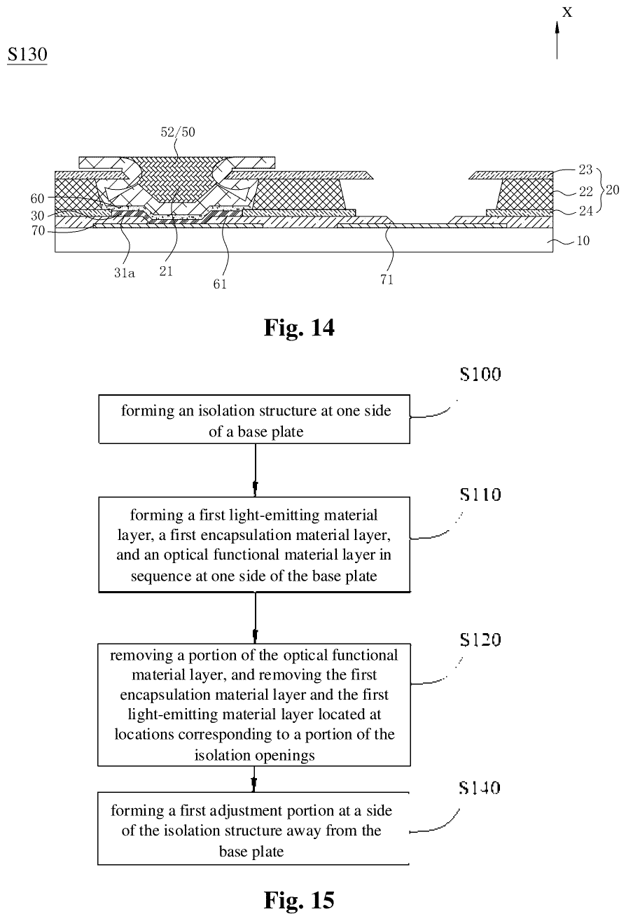

In some embodiments, referring to FIGS. 13 and 14, after step S120, the method further include:

Step S130: thinning the second adjustment portion.

Referring to FIG. 14, in step S130, the second adjustment portion 52 is thinned, so that a surface of the second adjustment portion away from the base plate 10 is parallel to a plane in which the base plate 10 is located. That is, the flatness of the surface of the second adjustment portion away from the base plate 10 can be improved by the thinning treatment, so as to facilitate the manufacturing of the subsequent film layer structures.

In addition, the second adjustment portion 52 is merely thinned, i.e., a portion of the second adjustment portion 52 is still located in the isolation opening 21, which helps to reduce the etching on the first encapsulation portion 411 and the first electrode 61, etc., by means of the second adjustment portion 52 in the subsequent manufacturing processes, so as to improve the manufacturing reliability of the display panel.

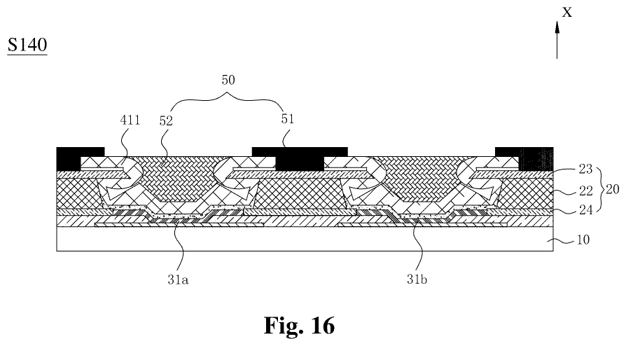

Referring to FIGS. 15 and 16, in some embodiments, after step S120, the method further includes:

Step S140: forming a first adjustment portion at a side of the isolation structure away from the base plate.

Referring to FIG. 16, in step S140, the isolation structure 20 includes a first isolation portion 22 and a second isolation portion 23 that are stacked in sequence along a direction away from the base plate 10, an orthographic projection of the first isolation portion 22 on the base plate 10 is located within an orthographic projection of the second isolation portion 23 on the base plate 10, and a light reflectivity corresponding to the first adjustment portion 51 is less than a light reflectivity corresponding to the second isolation portion 23. Optionally, the second adjustment portion 52 includes a color filter.

It should be noted that the first adjustment portion 51 is not manufactured together with the first light-emitting structure 31a, the first encapsulation portion 411, etc., but is manufactured after the first light-emitting structure 31a is manufactured. Further, under a condition that the display panel includes a plurality of light-emitting structures 31 for emitting lights of different colors, the first adjustment portion 51 may be manufactured after all of the light-emitting structures 31 are manufactured.

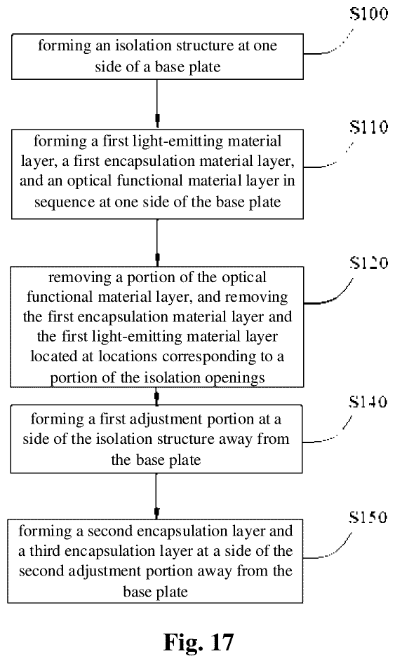

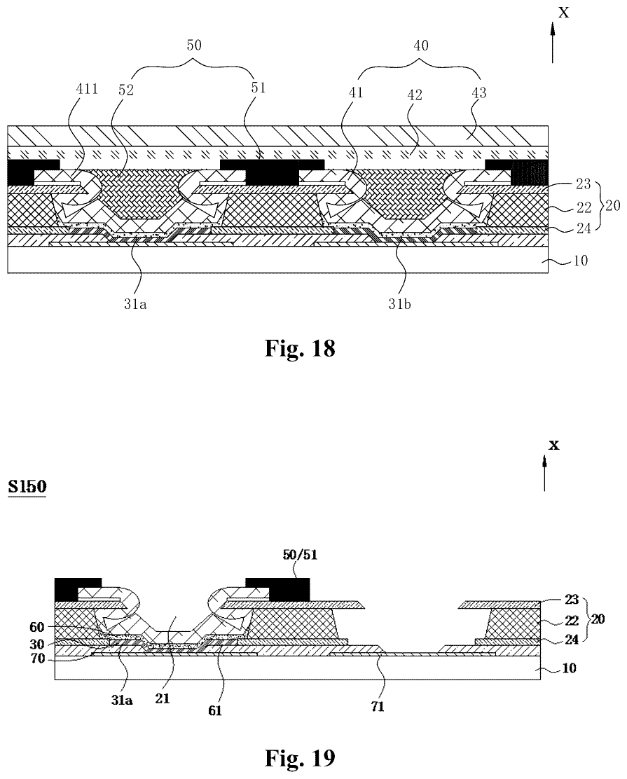

Further optionally, referring to FIGS. 17 and 18, after step S140, the method further includes:

Step S150: forming a second encapsulation layer and a third encapsulation layer at a side of the second adjustment portion away from the base plate.

In some embodiments, the optical functional material layer 50′ includes a first adjustment material layer.

Referring to FIG. 19, in step S120, the first adjustment material layer located at locations corresponding to all of the isolation openings is removed, and the first encapsulation material layer 411′ and the first light-emitting material layer 31a′ located at locations corresponding to the portion of the isolation openings are removed.

In the embodiments of the present application, both the first adjusting material layer and the first encapsulation material layer 411′ may have a whole surface structure, the first adjustment material layer located at locations corresponding to all of the isolation openings 21 is removed, and the first encapsulation material layer 411′ and the first light-emitting material layer 31a′ located at locations corresponding to the portion of the isolation openings 21 are removed, so as to form the first light-emitting structure 31a, the first encapsulation portion 411, and a first adjustment portion 51 at locations corresponding to the others of the isolation openings 21. Herein, the first adjustment portion 51 is at least partially located at a side of the isolation structure 20 away from the base plate 10. Optionally, the first adjustment portion 51 includes a black matrix.

It should be noted that although the first adjustment material layer in all of the isolation openings 21 may be removed, a portion of the first adjustment material layer may be kept in the isolation opening 21 as required. Optionally, at the others of the isolation openings 21, the first adjustment portion 51 is at least partially located within the isolation opening 21, and the first adjustment portion 51 located within the isolation opening 21 is connected with the first adjustment portion 51 located at the side of the isolation structure 20 away from the base plate 10.

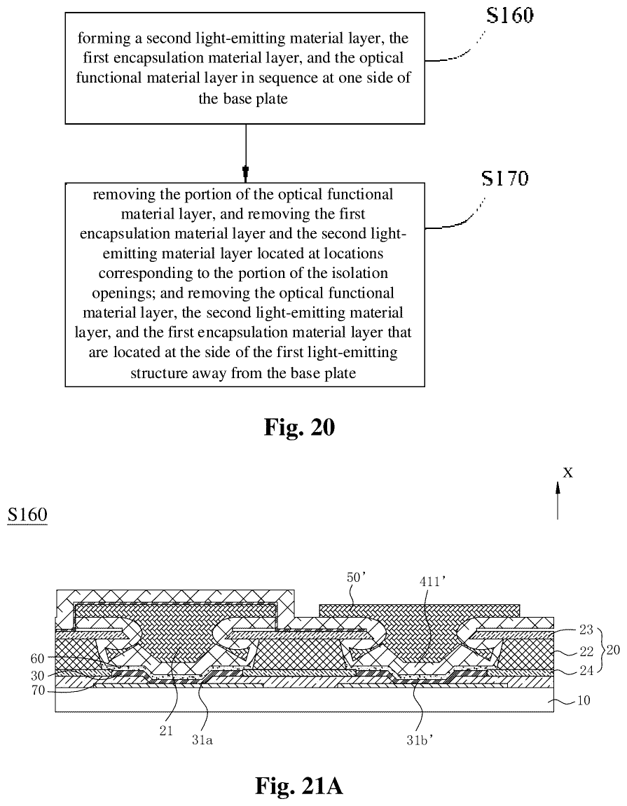

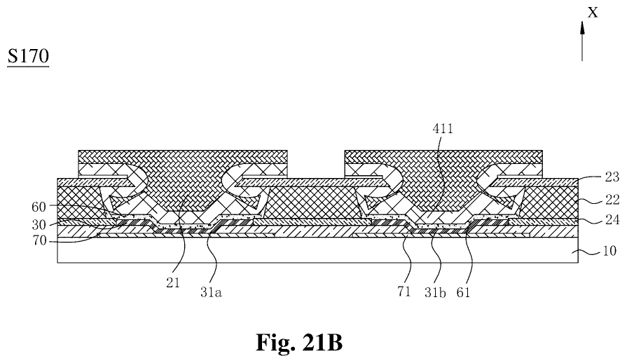

Referring to FIGS. 20 and 21, the method further includes:

Step S160: forming a second light-emitting material layer, the first encapsulation material layer, and the optical functional material layer in sequence at one side of the base plate. Referring to FIG. 21A, in step S160, a portion of the second light-emitting material layer 31b′, a portion of the first encapsulation material layer 411′, and a portion of the optical functional material layer 50′ are located at a side of the first light-emitting structure 31a away from the base plate 10. The second light-emitting material layer 31b′ is configured to form a second light-emitting structure 31b, and the first light-emitting structure 31a and the second light-emitting structure 31b are configured to emit lights of different colors. The first light-emitting structure 31a and the second light-emitting material layer 31b′ are simultaneously provided at locations corresponding to the portion of the isolation openings 21, and in the subsequent steps, the second light-emitting material layer 31b′ located at locations corresponding to the isolation openings 21 is required to be etched and removed, so that only the first light-emitting structure 31a is kept at locations corresponding to the isolation openings 21.

Step S170: removing the portion of the optical functional material layer, and removing the first encapsulation material layer and the second light-emitting material layer located at locations corresponding to the portion of the isolation openings; and removing the optical functional material layer, the second light-emitting material layer, and the first encapsulation material layer that are located at the side of the first light-emitting structure away from the base plate.

Referring to FIG. 21B, in step S170, a second light-emitting structure 31b and the first encapsulation portion 411 may be formed at locations corresponding to the others of the isolation openings 21, and the optical functional portion 50 may be formed; in which the first light-emitting structure 31a and the second light-emitting structure 31b are configured to emit lights of different colors.

It should be noted that the first light-emitting structure 31a and the second light-emitting structure 31b are light-emitting structures configured to emit lights of different colors, and optionally, the first light-emitting structure 31a and the second light-emitting structure 31b are respectively configured to emit lights of two of red color, blue color, and green color. Further optionally, in addition to the first light-emitting structure 31a and the second light-emitting structure 31b, the light-emitting structure may further include a third light-emitting structure configured to emit light of a different color, etc., and the manufacturing of the third light-emitting structure follows the above steps, which is not limited in the embodiments of the present application.

Although the implementations disclosed in the present application are described as above, the above implementations are described only for facilitating the understanding of the present application, rather than to limit the present application. Modifications and variations regarding forms and details may be made by any person skilled in the art related to the present application without departing from the gist and scope disclosed in the present application, but the protection scope of the present application is defined only by the appended claims.

The above implementations are only specific implementations of the present application, and those skilled in the art can clearly understand that other alternatives of the above connections may be referred to the corresponding processes in the above method embodiments, which are not repeated herein for convenience and brevity of the description. It should be understood that the protection scope of the present application is not limited to the above, and any person skilled in the art can easily think of various equivalent modifications or replacements within the technical scope disclosed in the present application, which should all be encompassed within the protection scope of the present application.

What is claimed is:

1. A display panel, comprising:
a base plate;
an isolation structure arranged at one side of the base plate and encircling a plurality of isolation openings;
a light-emitting functional layer arranged at one side of the base plate and comprising a light-emitting structure arranged corresponding to the isolation opening;
an encapsulation protection layer arranged at a side of the light-emitting functional layer away from the base plate and comprising a first encapsulation layer, the first encapsulation layer comprising a plurality of first encapsulation portions respectively arranged in the plurality of isolation openings; and
an optical functional portion comprising a plurality of second adjustment portions, the second adjustment portions located at a side of the first encapsulation portion away from the base plate, and the second adjustment portion at least partially embedded in the isolation opening, the second adjustment portion comprising a color filter.

2. The display panel according to claim 1, wherein the optical functional portion further comprises a first adjustment portion, and an orthographic projection of the first adjustment portion on the base plate is at least partially located between orthographic projections of adjacent second adjustment portions on the base plate; wherein the first adjustment portion comprises a light-absorbing material.

3. The display panel according to claim 2, the encapsulation protection layer further comprises a second encapsulation layer located at a side of the first encapsulation layer away from the base plate, and both the first adjustment portion and the second adjustment portions are at least partially located between the first encapsulation layer and the second encapsulation layer; and
the encapsulation protection layer further comprises a third encapsulation layer located at a side of the second encapsulation layer away from the base plate; the first encapsulation layer and the third encapsulation layer comprise an inorganic material, and the second encapsulation layer comprises an organic material.

4. The display panel according to claim 1, wherein the isolation structure comprises a first isolation portion and a second isolation portion stacked in sequence along a direction away from the base plate, and an orthographic projection of the first isolation portion on the base plate is located within an orthographic projection of the second isolation portion on the base plate.

5. A display panel, comprising:
a base plate;
an isolation structure arranged at one side of the base plate and encircling a plurality of isolation openings;
a light-emitting functional layer arranged at one side of the base plate and comprising a light-emitting structure arranged corresponding to the isolation opening;
an encapsulation protection layer arranged at a side of the light-emitting functional layer away from the base plate and partially embedded in the isolation opening; and
an optical functional portion arranged in the encapsulation protection layer, an orthographic projection of the optical functional portion on the base plate overlapping an orthographic projection of at least one of the isolation structure or the light-emitting structure on the base plate.

6. The display panel according to claim 5, wherein the encapsulation protection layer comprises a first encapsulation layer, a second encapsulation layer, and a third encapsulation layer stacked in sequence along a direction away from the base plate;
the first encapsulation layer comprises a plurality of first encapsulation portions respectively arranged in the plurality of isolation openings; and
the first encapsulation layer and the third encapsulation layer respectively comprise an inorganic material, and the second encapsulation layer comprises an organic material.

7. The display panel according to claim 6, wherein the optical functional portion is at least partially located between the first encapsulation layer and the second encapsulation layer; or
the optical functional portion is at least partially located between the second encapsulation layer and the third encapsulation layer.

8. The display panel according to claim 5, wherein the isolation structure comprises a first isolation portion and a second isolation portion stacked in sequence along a direction away from the base plate, and an orthographic projection of the first isolation portion on the base plate is located within an orthographic projection of the second isolation portion on the base plate;
the display panel further comprises a first electrode layer arranged between the light-emitting functional layer and the encapsulation protection layer, and the first electrode layer comprises a plurality of first electrodes arranged corresponding to the isolation openings; and
the first isolation portion comprises an electrically conductive material, and the first electrode is electrically connected with the first isolation portion.

9. The display panel according to claim 8, wherein the optical functional portion comprises a first adjustment portion arranged at a side of the second isolation portion away from the base plate;
a light reflectivity corresponding to the first adjustment portion is less than a light reflectivity corresponding to the second isolation portion;
the first adjustment portion comprises a black matrix; and
an orthographic projection of the first adjustment portion on the base plate covers the orthographic projection of the second isolation portion on the base plate.

10. The display panel according to claim 9, wherein
the encapsulation protection layer comprises a first encapsulation layer, a portion of the first encapsulation layer is arranged in contact with the isolation structure, and the first encapsulation layer comprises a first portion located at the side of the second isolation portion away from the base plate;
the first adjustment portion is at least partially located at a side of the first portion away from the base plate and arranged in contact with the first portion; and
the isolation structure encircles two or more isolation openings, the first encapsulation layer comprises a plurality of first encapsulation portions arranged corresponding to the two or more isolation openings, and first portions corresponding to at least a portion of adjacent first encapsulation portions are spaced apart;
wherein the first adjustment portion is at least partially located between adjacent the first portions.

11. The display panel according to claim 5, wherein the optical functional portion comprises a first adjustment portion arranged at a side of the isolation structure away from the base plate;
the first adjustment portion comprises a black matrix; and
an orthographic projection of the first adjustment portion on the base plate covers the orthographic projection of the isolation structure on the base plate.

12. The display panel according to claim 5, wherein the optical functional portion comprises a plurality of second adjustment portions, the second adjustment portion is at least partially embedded in the isolation opening and comprises a color filter.

13. The display panel according to claim 12, wherein the encapsulation protection layer comprises a first encapsulation layer, and the first encapsulation layer comprises a plurality of first encapsulation portions respectively arranged in the isolation openings;
the second adjustment portion is located at a side of the first encapsulation portions away from the base plate; and
the second adjustment portion is arranged in contact with the first encapsulation portion.

14. The display panel according to claim 13, wherein the optical functional portion further comprises a first adjustment portion, and an orthographic projection of the first adjustment portion on the base plate is at least partially located between orthographic projections of adjacent second adjustment portions on the base plate;
wherein the first adjustment portion comprises a light-absorbing material; and
the encapsulation protection layer further comprises a second encapsulation layer located at a side of the first encapsulation layer away from the base plate, and both the first adjustment portion and the second adjustment portion are at least partially located between the first encapsulation layer and the second encapsulation layer.

15. The display panel according to claim 14, the isolation structure comprises the first isolation portion and the second isolation portion stacked in sequence along the direction away from the base plate, and the orthographic projection of the first isolation portion on the base plate is located within the orthographic projection of the second isolation portion on the base plate;
the first encapsulation portion comprises the second portion arranged in contact with the first isolation portion, the third portion arranged in contact with the second isolation portion, and the fourth portion connected with the second portion and covering the light-emitting structure;
the third portion and the fourth portion are spaced apart in the thickness direction of the base plate to form a gap space, and the first adjustment portion is at least partially located at the side of the gap space away from the base plate; and
the first adjustment portion is partially located within the gap space.

16. A method for manufacturing a display panel, comprising:
forming an isolation structure at one side of a base plate, the isolation structure encircling a plurality of isolation openings;
forming a first light-emitting material layer, a first encapsulation material layer, and an optical functional material layer in sequence at one side of the base plate; and
removing a portion of the optical functional material layer, and removing the first encapsulation material layer and the first light-emitting material layer located at locations corresponding to a portion of the isolation openings, so as to form a first light-emitting structure and a first encapsulation portion at locations corresponding to the others of the isolation openings and form an optical functional portion; wherein the first light-emitting structure and the first encapsulation portion are arranged corresponding to the isolation opening, and an orthographic projection of the optical functional portion on the base plate overlaps an orthographic projection of at least one of the first light-emitting structure or the isolation structure on the base plate.

17. The method according to claim 16, wherein the optical functional material layer comprises a second adjustment material layer;
the removing the portion of the optical functional material layer, and removing the first encapsulation material layer and the first light-emitting material layer located at locations corresponding to the portion of the isolation openings comprises: removing the first light-emitting material layer, the first encapsulation material layer, and the second adjustment material layer located at locations corresponding to the portion of the isolation openings, so as to form the first light-emitting structure, the first encapsulation portion, and a second adjustment portion at locations corresponding to the others of the isolation openings; and
the second adjustment portion is at least partially located in the isolation opening.

18. The method according to claim 17, wherein after the removing the portion of the optical functional material layer, and removing the first encapsulation material layer and the first light-emitting material layer located at locations corresponding to the portion of the isolation openings, the method further comprises:
forming a first adjustment portion at a side of the isolation structure away from the base plate; the isolation structure comprising a first isolation portion and a second isolation portion stacked in sequence along a direction away from the base plate, an orthographic projection of the first isolation portion on the base plate being located within an orthographic projection of the second isolation portion on the base plate, and a light reflectivity corresponding to the first adjustment portion being less than a light reflectivity corresponding to the second isolation portion;
the second adjustment portion comprises a color filter; and the first adjustment portion comprises a black matrix; and
after the forming the first adjustment portion at the side of the isolation structure away from the base plate, the method further comprises: forming a second encapsulation layer and a third encapsulation layer at a side of the second adjustment portion away from the base plate.

19. The method according to claim 16, wherein the optical functional material layer comprises a first adjustment material layer;
the removing the portion of the optical functional material layer, and removing the first encapsulation material layer and the first light-emitting material layer located at locations corresponding to the portion of the isolation openings comprises: removing the first adjustment material layer located at locations corresponding to all of the isolation openings, and removing the first encapsulation material layer and the first light-emitting material layer located at locations corresponding to the portion of the isolation openings, so as to form the first light-emitting structure, the first encapsulation portion, and a first adjustment portion at locations corresponding to the others of the isolation openings; wherein at the others of the isolation openings, the first adjustment portion is at least partially located at a side of the isolation structure away from the base plate; and
the first adjustment portion comprises a black matrix.

20. The method according to claim 16, further comprising: forming a second light-emitting material layer, the first encapsulation material layer, and the optical functional material layer in sequence at one side of the base plate; a portion of the second light-emitting material layer, a portion of the first encapsulation material layer, and a portion of the optical functional material layer being located at a side of the first light-emitting structure away from the base plate; and
removing the portion of the optical functional material layer, and removing the first encapsulation material layer and the second light-emitting material layer located at locations corresponding to the portion of the isolation openings; and removing the optical functional material layer, the second light-emitting material layer, and the first encapsulation material layer that are located at the side of the first light-emitting structure away from the base plate; so as to form a second light-emitting structure and the first encapsulation portion at locations corresponding to the others of the isolation openings and form the optical functional portion; wherein the first light-emitting structure and the second light-emitting structure are configured to emit lights of different colors.
